(19) United States
(12) Patent Application Publication
(10) Pub. No.: US 2026/0300594 A1
(43) Pub. Date: Oct. 1, 2026

(54) ELECTRONIC DEVICE, COMPUTER-READABLE STORAGE MEDIUM AND METHOD FOR EXTRACTING PARASITIC CAPACITANCE OF INTERCONNECT LINES OF INTEGRATED CIRCUIT

(71) Applicant: HUAZHONG UNIVERSITY OF SCIENCE AND TECHNOLOGY, Hubei (CN)

(72) Inventors: Xingsheng Wang, Hubei (CN); Boyang Yan, Hubei (CN); Jian Zhang, Hubei (CN); Zifei Cai, Hubei (CN); Dejiang Mu, Hubei (CN); Fang Cheng, Hubei (CN); Xiangshui Miao, Hubei (CN)

(73) Assignee: HUAZHONG UNIVERSITY OF SCIENCE AND TECHNOLOGY, Hubei (CN)

(21) Appl. No.: 19/464,628

(22) Filed: Jan. 30, 2026

(30) Foreign Application Priority Data
Mar. 26, 2025 (CN) 202510361148.6
Dec. 1, 2025 (CN) 202511785449.8

(51) Int. Cl. G06F 30/367; G06N 3/048; G06N 3/0499

(52) U.S. Cl. CPC G06F 30/367; G06N 3/048; G06N 3/0499

(57) ABSTRACT

Constructing a set of surface sampling points and internal sampling points of conductors; constructing a parasitic capacitance matrix; generating a set of ideal surface potential values corresponding to the surface sampling points of each conductor; constructing a neural network structure, taking a mean square error between the ideal surface potential values corresponding to the surface sampling points and the output of the neural network as a loss function, taking the Green function of the Poisson equation as the activation function of the hidden layer, taking all equivalent point charge positions as the center coordinates of the activation function of the hidden layer; training the weight coefficients of each neuron in the hidden layer, correspondingly serving as the equivalent charge values of each equivalent point charge, obtaining the equivalent charge values of all equivalent point charges of each conductor, and updating the parasitic capacitance matrix.

### CROSS-REFERENCE TO RELATED APPLICATION

This application claims the priority benefit of China application no. 202510361148.6, filed on Mar. 26, 2025, and the China application no. 202511785449.8, filed on Dec. 1, 2025. The entirety of each of the above-mentioned patent applications is hereby incorporated by reference herein and made a part of this specification.

### BACKGROUND

### Technical Field

The disclosure belongs to the technical field related to integrated circuits, and more specifically, relates to a method for extracting parasitic capacitance of interconnect lines of an integrated circuit.

### Description of Related Art

With the continuous advancement in semiconductor manufacturing process technology, the dimension of integrated circuits have correspondingly decreased. In this context, the integration density of chips has significantly increased, leading to a more compact arrangement of interconnect lines. The distance between interconnect lines is becoming increasingly smaller, and at the same time, the variations in the manufacturing process of the interconnect lines themselves are becoming more pronounced. Consequently, the parasitic effects between interconnect lines have become more severe, and parasitic parameters, particularly parasitic capacitance, have a more significant impact on the circuit. Accurately extracting these parasitic effect parameters has become one of the critical issues in the field of integrated circuits.

Currently, mainstream parasitic capacitance field solvers for interconnect lines can primarily be divided into two categories based on their solving principles. One category includes conventional discrete numerical methods used to solve physical field equations, such as the finite difference method and boundary element method. The other category involves integral solving methods, such as the floating random walk method, which utilizes floating random walks to transform the calculation of conductor charge into a Monte Carlo integral. The floating random walk method offers higher computational efficiency and accuracy compared to other conventional numerical methods. However, its results exhibit variance, leading to poorer symmetry in the interconnect lines capacitance matrix. Furthermore, it often faces challenges when dealing with conductors of non-Manhattan shapes (due to process variability) and complex dielectric distributions. Conventional discrete numerical methods offer less accuracy compared to the random shape methods and necessitate significant computational costs for discretizing grids, especially for conductors with non-Manhattan shapes.

Rapidly advancing neural networks are playing an increasingly significant role in the field of electronic design automation for integrated circuits. Substantial progress has been made in research on data-driven neural network methods for parasitic capacitance prediction. However, there is a relative scarcity of studies focusing on the direct resolution of parasitic capacitance using neural networks. Moreover, none have proposed a machine learning method for solving parasitic capacitance fields that is equivalent in status to boundary element methods or similar techniques.

### SUMMARY

In light of the aforementioned deficiencies or needs of improvement for the existing technology, this disclosure provides a method for extracting parasitic capacitance of interconnect lines of an integrated circuit. The objective is to organically combine artificial neural networks with the physical problem of parasitic capacitance calculation, thereby fully leveraging the flexible and efficient characteristics of neural networks, and achieving high-precision extraction of parasitic capacitance.

To achieve the aforementioned objectives, in accordance with an aspect of the present disclosure, a method for extracting parasitic capacitance of interconnect lines of an integrated circuit is provided, including:

S1: Constructing a sequence of position coordinates of surface sampling points and internal sampling points of each of the conductors for which parasitic capacitance is to be extracted, and serving each of the internal sampling points as a position of an equivalent point charge;

S2: Acquiring a set of potential values of all of the surface sampling points, wherein the set of the potential values of the surface sampling points is provided for constructing a sampling point potential matrix;

S3: Constructing a neural network structure composed of an input layer, a single hidden layer and an output layer, wherein the position coordinates of the surface sampling points serve as an input of the neural network, a mean square error between ideal surface potential values corresponding to the surface sampling points one by one and an output of the neural network serves as a loss function, the number of neurons is the same as the number of all equivalent point charges corresponding to all conductors, a Green function of a Poisson equation in a three-dimensional space serves as an activation function of the single hidden layer, and position coordinates of all of the equivalent point charges serve as center coordinates of the activation function of the hidden layer; based on the set of the position coordinates of the surface sampling points of all of the conductors and the corresponding set of the ideal surface potential values one by one, training weight coefficients of each of the neurons in the single hidden layer of the neural network, correspondingly serving as equivalent charge values of each of the equivalent point charges to obtain the equivalent charge values of all of the equivalent point charges in each of the conductors; and

S4: Adopting the equivalent charge values of all of the equivalent point charges in each of the conductors to calculate a charge quantity of the conductor to calculate an interconnect capacitance between every two of the conductors, and calculating and acquiring a parasitic capacitance matrix of the conductors.

In general, compared with the related art, the technical solution provided by the disclosure conceived through the above technical solution mainly has the following advantageous effects:

1. The present disclosure provides a method for extracting parasitic capacitance of interconnect lines of an integrated circuit. The fundamental principle involves assuming the presence of numerous equivalent point charges within each of the conductors. The collective effect of these equivalent point charges ensures that the surface potential values of each of the conductors reach the desired level, thereby allowing the calculation of the parasitic capacitance matrix. Specifically, this is achieved by constructing the neural network structure composed of the input layer, the single hidden layer, and the output layer. This structure incorporates the Green function of the Poisson equation in three-dimensional space as the activation function (i.e., kernel function) of the single hidden layer, and uses the positional coordinates of all equivalent point charges as the central coordinates of the kernel function of the single hidden layer. This neural network may compute the equivalent charge values of all equivalent point charges, thus enabling the calculation of the capacitance matrix. As the first method driven entirely by machine learning for the numerical computation of parasitic capacitance, it is underpinned by robust theoretical support, distinct physical significance, and interpretability, ensuring the reliability of the solution results. Compared to conventional algorithms such as random walk and finite element methods, this method surpasses the accuracy of the finite element and other conventional mesh methods in computing major capacitances. It is only slightly less accurate than the highest precision random walk method. In some special scenarios (such as when conductors are spaced far apart), the variance of computation results in the same time frame is smaller than that of the random walk method, indicating a higher symmetry in the parasitic capacitance matrix computed by this method. Furthermore, due to the structural characteristics of the neural network, different training parameters may be selected, granting greater computational flexibility. The construction method of the neural network and the parameter training methods ensure that the computation of the interconnect capacitance matrix is not constrained by process deviations and random fluctuations in the interconnect line conductor structure (for example, when dealing with interconnect line conductor structures with irregular surfaces, initial training is conducted: training a neural network model for interconnect line conductors under ideal conditions, and ensuring a geometrically similar distribution of equivalent point charges, then altering the sampling point positions to map onto the actual surface of conductors with process variations, maintaining constant charge, and continuing to approximate the geometric distribution of equivalent point charges and sampling points. Finally, this serves as the initial state for neural network training to simulate the capacitance scenario of interconnect line conductors with process deviations, achieving high-precision computation of the parasitic capacitance matrix for interconnect line conductors with irregular surfaces in a rapid manner). This method organically combines artificial neural networks with the physical problem of parasitic capacitance computation, fully leveraging the flexible and efficient characteristics of neural networks, and offers a novel approach to the numerical solution of the physical problem of parasitic capacitance.

2. The present disclosure provides a method for surface sampling points, wherein sampling is conducted on the surface of the interconnect line conductor structure to acquire a set of position coordinates of the surface sampling points as input for the constructed neural network model. Compared to conventional methods such as the finite element method and other full-space discretization approaches, this technique reduces the dimensionality of the problem. Furthermore, the need for mesh discretization of the interconnect line conductor structure is eliminated, thereby conserving the computational cost associated with mesh generation.

3. In the training scheme provided by this disclosure, after initially training the parameters using the least squares method, another set of position coordinates of the internal sampling points is constructed for each of the conductors. Based on the equivalent charge values of all equivalent point charges corresponding to each of the conductors obtained from the current training, the electrostatic potential collectively excited by all equivalent point charges on the conductor at each surface sampling point is calculated. The difference between the electrostatic potential corresponding to each surface sampling point and the ideal surface potential value of the conductor is determined. The mean square error between these differences, which correspond to the surface sampling points one by one, and the output of the neural network serves as the loss function. The neural network structure is then reconfigured and retrained to obtain the equivalent charge values of all equivalent point charges for each of the conductors, as determined by the two sets of the position coordinates of the internal sampling points. This scheme reduces the error in the least squares training results through multiple training iterations, thereby ensuring the accuracy of the final calculation results of the interconnect capacitance matrix.

4. The present disclosure employs batch processing techniques and random matrix compression techniques to significantly reduce the dimension of matrices that need to be stored. It further transforms large-scale least squares problems into smaller matrix solving problems, thereby significantly reducing memory usage and greatly accelerating the solving process. Simultaneously, the multi-stage residual fitting technique enables the disclosure to achieve high-precision capacitance extraction through iterative error compensation at smaller compression dimension, ensuring that both memory usage and solving speed surpass those of mainstream commercial software based on grid methods, all while maintaining accuracy.

### BRIEF DESCRIPTION OF THE DRAWINGS

FIG. 1 is a flowchart of a method for extracting parasitic capacitance of interconnect lines of an integrated circuit provided by an embodiment of the disclosure.

FIG. 2 is a schematic diagram of a structure and training method of a physically-informed extreme learning machine provided by an embodiment of the disclosure.

FIG. 3 is an overall flowchart of extracting parasitic capacitance provided by an embodiment of the disclosure.

FIG. 4 is a flowchart of constructing a neural network model-physically-informed extreme learning machine and calculating an interconnect capacitance matrix of conductors provided by an embodiment of the disclosure.

FIG. 5 is a flowchart of constructing a neural network model-physically-informed extreme learning machine and calculating an interconnect capacitance matrix of conductors provided by yet another embodiment of the disclosure.

FIG. 6 is a comparison diagram of effects before and after using random matrix compression provided by an embodiment of the disclosure.

FIG. 7 is a diagram of an interconnect line conductor structure provided by an embodiment of the disclosure.

FIG. 8 is a comparison diagram of a capacitance matrix provided by an embodiment of the disclosure and a capacitance matrix obtained by other commercial software.

### DESCRIPTION OF THE EMBODIMENTS

In order to make the objectives, technical solutions, and advantages of this disclosure more clear and comprehensible, the disclosure will be further explained in detail below in conjunction with the accompanying drawings and embodiments. It should be understood that the specific embodiments described herein are merely for the purpose of illustrating the disclosure and are not intended to limit the disclosure. Furthermore, the technical features involved in the various embodiments of the disclosure described below can be combined with each other as long as they do not conflict with one another.

### Embodiment 1

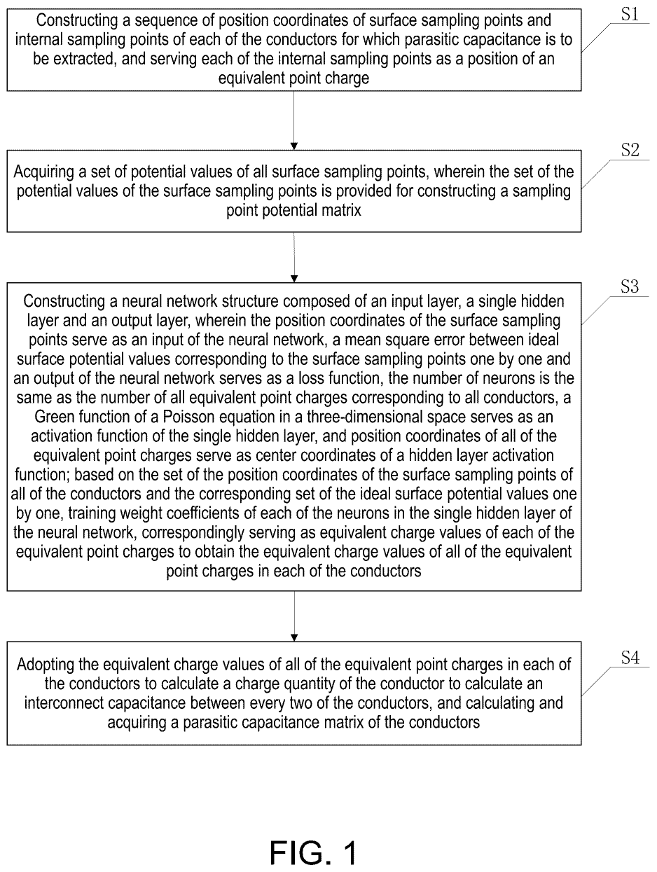

A method for extracting parasitic capacitance of interconnect lines of an integrated circuit, as shown in FIG. 1, includes:
S1: Constructing a sequence of position coordinates of surface sampling points and internal sampling points of each of the conductors for which parasitic capacitance is to be extracted, and serving each of the internal sampling points as a position of an equivalent point charge;
S2: Acquiring a set of potential values of all of the surface sampling points, wherein the set of the potential values of the surface sampling points is provided for constructing a sampling point potential matrix;
S3: Constructing a neural network structure composed of an input layer, a single hidden layer and an output layer, wherein the position coordinates of the surface sampling points serve as an input of the neural network, a mean square error between ideal surface potential values corresponding to the surface sampling points one by one and an output of the neural network serves as a loss function, the number of neurons is the same as the number of all equivalent point charges corresponding to all conductors, a Green function of a Poisson equation in a three-dimensional space serves as an activation function of the single hidden layer, and position coordinates of all of the equivalent point charges serve as center coordinates of the activation function of the hidden layer; based on the set of the position coordinates of the surface sampling points of all of the conductors and the corresponding set of the ideal surface potential values one by one, training weight coefficients of each of the neurons in the single hidden layer of the neural network, correspondingly serving as equivalent charge values of each of the equivalent point charges to obtain the equivalent charge values of all of the equivalent point charges in each of the conductors; and
S4: Adopting the equivalent charge values of all of the equivalent point charges in each of the conductors to calculate a charge quantity of the conductor to calculate an interconnect capacitance between every two of the conductors, and calculating and acquiring a parasitic capacitance matrix of the conductors.

It should be noted that the interconnect capacitance is the parasitic capacitance. The above Green function is

$$\frac{1}{4 π ε} \cdot {( ‖ r - {r}^{′} ‖ )}^{- 1} ,$$

the position coordinates of all equivalent point charges are taken as the center coordinates r′ of the single hidden layer kernel function, ¿ represents the dielectric constant, and r represents the position coordinates of the surface sampling points. The set of position coordinates of the surface sampling points of the conductors acquired above is taken as the input, the positions of the equivalent point charges acquired above are taken as the initial positions of the neurons of the hidden layer, and the Green function

$$\frac{1}{4 π ε} \cdot {( ‖ r - {r}^{′} ‖ )}^{- 1}$$

of the Poisson equation in three-dimensional space is taken as the activation function of the hidden layer, wherein ∥r−r′∥ is an Euclidean distance between each element in the input surface sample coordinate set and all hidden layer neurons. The activation function maps a relationship between an input quantity and an output quantity to a linear space, the mean square error between ideal surface potential values of the conductors configured above and an output of the neural network is taken as the loss function, and the equivalent charge values of the equivalent point charges are obtained by solving a coefficient matrix of a linear equation system of the input quantity and the output quantity in the linear space.

In S4, when calculating and updating the parasitic capacitance matrix of the conductor structure, since electric fields excited by different point charges at the same position in space are linearly superimposed, according to a relationship formula

$$C = \frac{Q}{V}$$

between the surface potential and the conductor charge capacitance, the equivalent charge values of the equivalent point charges inside each of the conductors obtained are summed to obtain a self-capacitance when a main conductor is the conductor as selected above and a mutual capacitance therebetween and slave conductors, and results are written into the corresponding positions in the interconnect capacitance matrix of the conductors.

Furthermore, in S4, it is determined whether all conductors have previously been designated as primary conductors. If there is any conductor that has not been designated as a primary conductor, designate the conductor as a new primary conductor, and set the ideal surface potential value thereof to 1. All other conductors are set as secondary conductors, with their ideal surface potential value set to 0. A set of potential values corresponding to the set of surface sampling points one by one is generated based on the ideal surface potential value of each of the conductors. The steps of constructing and training the neural network are repeated. If all conductors have already been designated as the primary conductors, then the interconnect capacitance matrix is computed and output. The principle for selecting another primary conductor is that the conductor has not been previously designated as the primary conductor; if there are multiple conductors that have not been so designated, there is no restriction on the order of selection.

The method for extracting parasitic capacitance of interconnect lines of the integrated circuit described in this embodiment is the first machine learning-based solution for solving parasitic capacitance of interconnect lines that is entirely driven by physical principles rather than data. The method employs the neural network to directly solve the interconnect parasitic capacitance matrix of interconnected conductor structures. Similar to the basic concept of the conventional boundary element method for solving parasitic capacitance of interconnect lines, the solving principle of the method is distinctly meaningful and interpretable in a physical sense. This method uses the Green function of the Poisson equation as the activation function in the hidden layer of the extreme learning machine and liberates the position of the equivalent point charge (Green function excitation source) from the surface of the conductor to the interior thereof, providing greater computational flexibility compared to conventional methods.

The method for extracting parasitic capacitance of the interconnect lines of the integrated circuit, as provided in this embodiment, involves sampling on the surface of the interconnect line conductor structure to obtain model inputs and sampling within the conductor to obtain the excitation source of the Green function (i.e., neurons). Therefore, the computational process of this method is not constrained by process deviations and random fluctuations of the interconnect line conductor structure. For example, preferably, when the conductor with an irregular surface exists in the integrated circuit, each of the conductors with the irregular surface is regarded as a conductor with a regular surface (an irregular surface has protrusions or depressions, while a regular surface is flat; “regarded as” means initially considering the conductor with an irregular surface as one with a flat surface) to execute Steps S1 to S3. Furthermore, according to the actual surface of the conductor with the irregular surface, Steps S1 to S3 are executed again, where the number of the surface sampling points and the internal sampling points obtained in both samplings are identical, and the initial values of the weight coefficients of each of the neurons in the neural network during the second execution of Steps S1 to S3 are the weight coefficients obtained after the first execution of Steps S1 to S3. In other words, when dealing with interconnect line conductor structures with irregular surfaces, pre-training is first conducted: training the neural network model for the conductors of interconnect lines under ideal conditions and making the distribution of equivalent point charges geometrically similar. Then, the positions of the sampling points are altered to map them onto the actual surface of the conductor with process variations, maintaining the charge constant, continuing to make the distribution of equivalent point charges and sampling points geometrically approximate. Finally, this is used as the initial state of the neural network for training, simulating the capacitance conditions of the interconnect line conductors with process deviations, enabling rapid and high-precision solving of the parasitic capacitance matrix of the interconnect line conductors with irregular surfaces.

Furthermore, the method for extracting the parasitic capacitance of interconnect lines provided in this embodiment is the machine learning approach driven entirely by the physical layer for interconnect line conductor structures. As such, this method possesses a high degree of parallelization and affinity with both software and hardware. With advancements in hardware performance, such as GPUs, and improvements in machine learning software frameworks, it is anticipated that this will result in faster computational speeds and higher computational efficiency.

As a preferred embodiment, the method for constructing the set of coordinates for the surface sampling points is as follows:

Reading a physical layout binary file of the integrated circuit and a file recording information of each process layer in the integrated circuit, and establishing a three-dimensional spatial model of each of the conductors in the integrated circuit;

According to the three-dimensional spatial model of each of the conductors, sampling a preset number of sampling points on a surface of the conductor through a uniform random sampling mode or a uniform grid sampling mode, and acquiring the set of the position coordinates of the surface sampling points.

As a preferred embodiment, the construction method for the set of the position coordinates of the internal sampling points is as follows:
Reading a physical layout binary file of the integrated circuit and a file recording information of each process layer in the integrated circuit, and establishing a three-dimensional spatial model of each of the conductors in the integrated circuit;
According to the three-dimensional spatial model of each of the conductors, configuring all internal sampling points to be distributed on the surface of a three-dimensional closed solid structure obtained by proportionally reducing each original side length of the conductor according to a preset sampling ratio parameter a, sampling the interior of the conductor, and acquiring the set of the position coordinates of the internal sampling points.

The process layout file for the interconnect line conductors includes a binary file describing the physical layout of the integrated circuit and a file recording the information of each process layer. The binary file describing the physical layout of the integrated circuit is commonly known as a GDSII file in the post-layout process of integrated circuits. As for the content of the file regarding each process layer, if it is a metal layer, the content includes the name of the metal layer, layer number, data type, height, and thickness. If it is a via layer, the content includes the name of the via layer, layer number, data type, and the names of the metal layers connected above and below.

The GDSII Stream Format (GDSII) is a database file format utilized for the data interchange of integrated circuit layouts, and it has effectively become the de facto industry standard. GDSII is a binary file that contains the planar geometric shapes, text or labels, and other pertinent information within integrated circuit layouts, and it may be organized in a hierarchical structure. GDSII data may be used to reconstruct all or part of the layout information.

According to the process layout file of the interconnect line conductors, the coordinate sets of sampling points on the three-dimensional space surface and within the three-dimensional space of the conductor structure are obtained, respectively. As an exemplary embodiment, the tool provided to read the binary files describing the physical layout of integrated circuits is the Python package “python-gdsii”. “Python-gdsii” is a Python library that may be used to read, create, modify, and save GDSII files. This package also includes methods for converting binary GDS files into other simple text formats.

In the internal sampling of various interconnect line conductors, the sampling rules and the density and distribution characteristics of the sampling points are initially established. The sampling rules may be set as uniformly distributed random sampling or grid sampling, among others. The positional distribution of sampling points is typically determined by a three-dimensional closed geometric surface, which is formed by proportionally reducing each edge length of the original conductor according to a sampling ratio parameter a. For instance, sampling is conducted on the surface of a three-dimensional closed geometric structure obtained by reducing the edge length of the conductor to a=0.8 times or a=0.9 times the original length, according to the established sampling rules and density.

The method for extracting the parasitic capacitance of interconnect lines provided by this disclosure involves sampling on the surface of the interconnect line conductor structure to obtain model inputs. Compared with conventional finite element methods, this approach reduces the dimensionality of the problem. When solving a three-dimensional interconnect line conductor structure, sampling is required only on the surface, and when solving a two-dimensional interconnect line conductor structure, sampling is required only on the boundary. Moreover, there is no need for mesh discretization of the interconnect line conductor structure. For example, when calculating the mutual capacitance of an isolated metal sphere, conventional boundary element algorithms require complex mesh discretization of a surface of the sphere. In contrast, by placing the equivalent point charge, represented by the Green function excitation source of the Poisson equation, at the center of the sphere, it is only necessary to solve for this unknown variable to determine the electric field distribution in the space outside the conductor under given voltage conditions. Therefore, this method achieves higher computational efficiency.

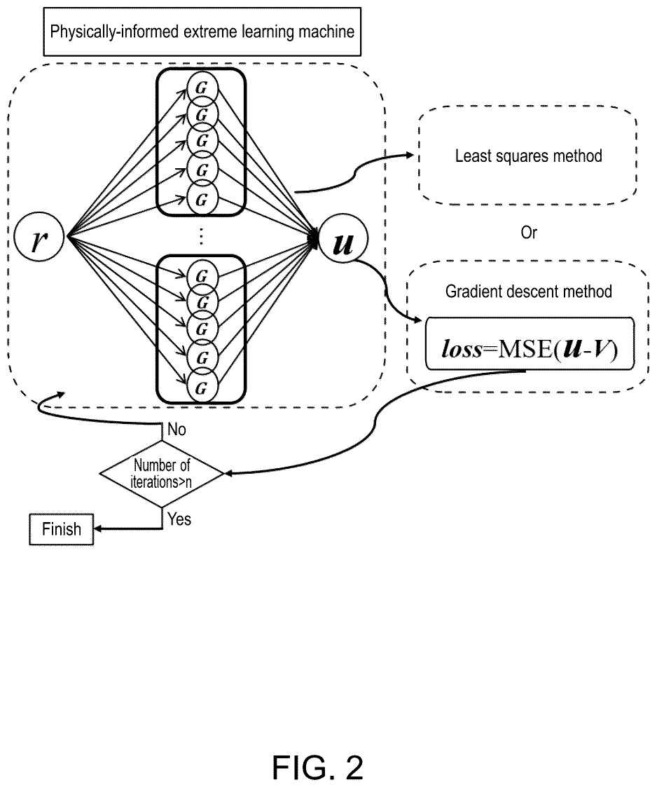

In a preferred embodiment, the weight coefficients of neurons in the single hidden layer of the neural network in S3 may be trained using either the gradient descent method or the least squares method. In this embodiment, the neural network may be trained using the method of a physically informed neural network, specifically by employing the gradient descent method for backpropagation, or by using the least squares method for training. In this context, the neural network is referred to as a physically-informed extreme learning machine, as illustrated in FIG. 2. When utilizing the gradient descent method, the mean square error function of the output value u of the model and the ideal surface potential value V of the conductor is used as the loss function during the backpropagation process. An optimizer employed may be Adam, AdamW, LBFGS, among others, without limitation. The software frameworks used for constructing and training this neural network may include Pytorch, Tensorflow, Jax, and others, without restriction. When training the network using the physically informed neural network method, i.e., backpropagation via gradient descent, the position coordinate information of the neurons may be optionally designated as a training parameter. Selecting it as a training parameter may require a longer training time, which could enhance the accuracy of the solution results. Moreover, during training with the gradient descent method, batch training methods may also be employed. The specific operation involves sequentially training multiple different physically-informed extreme learning machine models, where subsequent models are used to fit the residuals of the previously trained models.

The neural network model, known as the physically-informed extreme learning machine, constructed based on the set of coordinates of equivalent point charges, integrates the principles of physically-informed neural networks and extreme learning machines, featuring only the single hidden layer. This model may be optimized using two training methods, namely the least squares method and the gradient descent method, corresponding respectively to the training approaches of the extreme learning machine and the physically-informed neural network.

If the training method of Extreme Learning Machine (ELM) is adopted, where the weight coefficients are directly determined through an analytical method (specifically, the least squares method), there exists an optimization potential for the residual fitting of the weight coefficients obtained through this training method. Therefore, further training may be conducted to reduce the residual fitting of this training method. As an optimal implementation approach, when employing the least squares method to train the weight coefficients of neurons in the single hidden layer of the neural network, after the least squares training is completed, another set of the position coordinates of the internal sampling points is constructed for each of the conductors. Based on the equivalent charge values of all of the equivalent point charges corresponding to each of the conductors obtained from the current training, an electrostatic potential excited by all of the equivalent point charges on the conductor at each of the surface sampling points is calculated. The difference between the electrostatic potential corresponding to each of the surface sampling points and the ideal surface potential value of the conductor is determined. The mean square error between these differences, corresponding to the surface sampling points one by one, and the output of the neural network is used as the loss function. The neural network structure is reconstructed and trained anew to obtain the equivalent charge values of all of the equivalent point charges for each of the conductors, as determined by two sets of the position coordinates of the internal sampling points.

If the gradient descent method is employed, upon reaching the termination condition of the iteration, the equivalent charge values of all equivalent point charges within each of the conductors corresponding to the set of neuron weight coefficients that yield the best predictive performance are determined, and proceed to Step S4. If the least squares method is adopted, upon completion of Step S3, the equivalent charge values of all equivalent point charges within each of the conductors are determined, and proceed to Step S4.

The method for extracting parasitic capacitance of interconnect lines provided in this embodiment allows for flexible configuration of the neural network training method according to various practical scenarios. Regardless of the type of training method employed, a multi-stage training strategy may be adopted. This involves sequentially training multiple different neural networks, where subsequent models are utilized to fit the residuals of previously trained models. As a result, this approach achieves a high degree of accuracy.

It should be noted that when using the least squares method for training, it is preferable to construct two sets of the position coordinates of the internal sampling points and perform neural network construction and training twice to improve accuracy. The construction methods for these two sets of position coordinates of the internal sampling points may be identical. For example, as previously mentioned, based on the three-dimensional spatial model of each of the conductors, internal sampling points are set to be distributed entirely on the surface of the three-dimensional closed structure obtained by proportionally reducing the original dimension of the conductor according to the preset sampling ratio parameter a. Sampling is conducted internally for the conductor to obtain the set of the position coordinates of the internal sampling points. The value of the sampling ratio parameter a may be adjusted according to actual needs. As an example, the first set of the position coordinates of the internal sampling points corresponds to a∈[0.8,0.95], while the second set of the position coordinates of the internal sampling points corresponds to a>0.95, which involves appropriately increasing the sampling ratio parameter a to obtain internal points closer to the surface. This approach may accelerate the reduction of the loss function and residuals in the subsequent training and fitting process, offering practical application value. The positions of the equivalent point charges in the second sampling do not overlap with the positions in the set of coordinates from the first sampling.

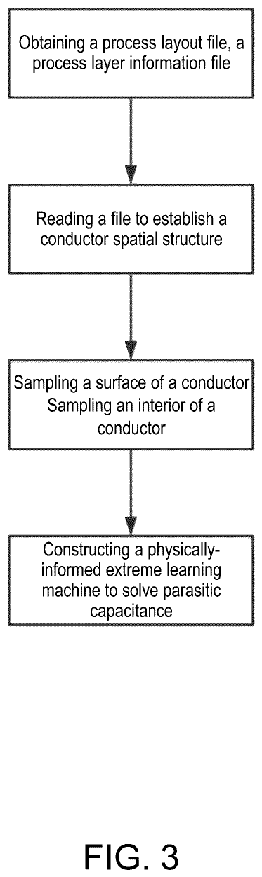

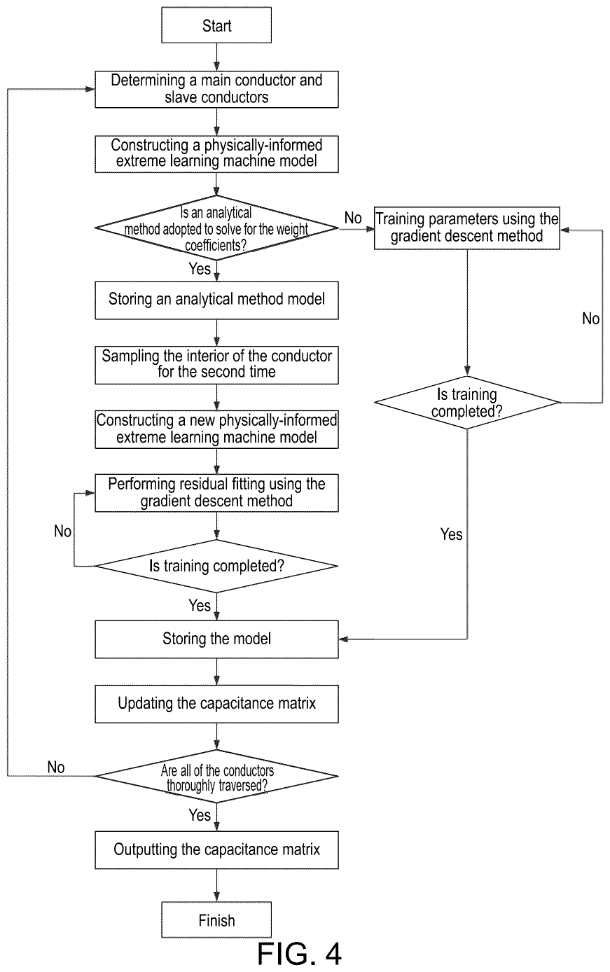

In an optional embodiment, please refer to FIG. 3, FIG. 3 is a flowchart for extracting parasitic capacitance. Refer also to FIG. 4, FIG. 4 illustrates the workflow of the parasitic capacitance extraction process. Through the aforementioned steps, the accurate calculation of the interconnect parasitic capacitance parameter matrix for interconnect line conductor structures may be achieved.

Furthermore, optionally, the process of training the weight coefficients of neurons in the single hidden layer of the neural network using the least squares method also includes the following steps:

S31: Constructing a sampling point potential matrix B, specifically including: sequentially selecting one of the N conductors constructed in the above S1, setting the potential value of the surface sampling points corresponding to this conductor to 1, and setting the potential values of the surface sampling points corresponding to the remaining conductors to 0, thereby obtaining a right-hand side vector b; with a length of b, wherein the subscript i indicates that this is the i-th conductor selected sequentially, and obtaining the set of potential values of all of the surface sampling points, i.e., a right-hand side vector; combining the N right-hand side vectors into a right-hand side matrix B=[b₁ . . . b_{N}]; it should be noted that it is assumed that Step S1 constructs the geometric model of the interconnect line conductor system from which the parasitic capacitance is to be extracted, including a total of N conductors; constructing a sequence of position coordinates of the surface sampling points of all conductors with the length of b and a sequence of position coordinates of the internal sampling points of all conductors with the length of p; taking each of the internal sampling points as a position of an equivalent point charge for subsequently calculating the potential values of all surface sampling points. It should be noted that the potential matrix B is also referred to as the right-hand side matrix B.

Sequentially obtaining N right-hand side vectors from b₁ to b_{N}, combining these N right-hand side vectors into a right-hand side matrix B=[b₁ . . . b_{N}], wherein the dimension of B are b×N;

S32: Constructing a random matrix X and a matrix U, wherein the matrix U is constructed according to the following rules: sequentially selecting one of the N conductors, setting the values of the internal sampling points of the conductor to 1, setting the values of the internal sampling points of the remaining conductors to 0, and obtaining the set of values of all of the internal sampling points, i.e., a vector; combining the N vectors into a matrix U=[u₁ . . . u_{N}]; combining X and U into a new matrix S=[X U], specifically, constructing a random matrix X, wherein the dimension of N′ are p×k, and the matrix elements in X preferably follow a Gaussian distribution

$$N ( 0 , \frac{1}{k} ) ;$$

constructing a matrix U, wherein the dimension of U are p×N, and the matrix U is constructed according to the following rules:
Sequentially selecting one of the N conductors constructed in S1, setting the values of the internal sampling points corresponding to this conductor to 1, and setting the values of the internal sampling points corresponding to the remaining conductors to 0, thereby obtaining a vector uᵢ with the length of p, wherein the subscript i indicates that this is the i-th conductor selected sequentially;
Sequentially obtaining the N vectors from u₁ to u_{N}, combining these N vectors into a matrix U=[u₁ . . . u_{N}], wherein the dimension of U is p×N;
Combining the matrix X and the matrix U into a new matrix S=[X U], wherein the dimension of the matrix S is p×(N+k);
S33: Extracting rows from the right-hand side matrix B in batches sequentially, wherein the number of the rows extracted in each of the batches is B_{batch}, obtaining a new right-hand side matrix B_{batch}, wherein the dimension of B batch is b_{batch}×N, wherein B_{batch} is not greater than a positive integer MAX; simultaneously constructing a left-hand side matrix G_{batch}, wherein the number of matrix rows constructed in each of the batches is b_{batch}, the dimension of G_{batch} is b_{patch}×p, and the matrix element G_{batch} in (G_{batch}) ma represents a value of the Green function of the Poisson equation corresponding to a distance between an m-th coordinate in the sequence of the position coordinates of the surface sampling points and an n-th coordinate in the sequence of the position coordinates of the internal sampling points; multiplying the matrix S to the right of the left-hand side matrix G_{batch} to obtain the left-hand side matrix G_{batch}S, wherein the dimension of the left-hand side matrix G_{batch}S is b_{batch}×(N+k); left-multiplying a transpose of the matrix G_{batch}S to the left-hand side matrix G_{batch}S and the right-hand side matrix B_{batch} respectively, obtaining the left-hand side matrix (G_{batch}S)^{T}G_{batch}S and the right-hand side matrix (G_{batch}S)^{T}B_{batch} respectively, wherein the dimension of the left-hand side matrix (G_{batch}S)^{T}G_{batch}S is (N+k)×(N+k), and the dimension of the right-hand side matrix (G_{batch}S)^{T}B_{batch} is (N+k)×N; after processing all batches, obtaining the sum of the final left-hand side matrix (GS)^{T}GS and the sum of the right-hand side matrix (GS)^{T}B, serving as the final left-hand side matrix and right-hand side matrix to be solved;
Specifically, calculating the left-hand side matrix (G_{batch}S)^{T}G_{batch}S and the right-hand side matrix (G_{batch}S)^{T}B_{batch} of the first batch;
Calculating the left-hand side matrix (G_{batch}S)^{T}G_{batch}S and the right-hand side matrix (G_{batch}S)^{T}B_{batch} of the next batch;
Summing the left-hand side matrices and the right-hand side matrices of the first two batches respectively, and storing the sum of the left-hand side matrices and the sum of the right-hand side matrices respectively;
Sequentially calculating the left-hand side matrix (G_{batch}S)^{T}G_{batch}S and the right-hand side matrix (G_{batch}S)^{T}B_{batch} of the next batch, and accumulating the left-hand side matrix (G_{batch}S)^{T}G_{batch}S and the right-hand side matrix (G_{batch}S)^{T}B_{batch} obtained from each calculation into the previously obtained sum of the left-hand side matrices and the sum of the right-hand side matrices respectively, and storing the newly obtained sum of the left-hand side matrices and the sum of the right-hand side matrices respectively;

After processing all batches according to the above steps, obtaining the sum of the final left-hand side matrix (GS)^{T}GS and the sum of the right-hand side matrix (GS)^{T}B, serving as the final left-hand side matrix and right-hand side matrix to be solved.

Further, solving the matrix equation (GS)^{T}GS\hat{Q}=(GS)^{T}B, wherein \hat{Q} is the matrix to be solved, and the dimension of the matrix \hat{Q} is (N+k)×N;
Secondly, restoring \hat{Q} back to the real matrix Q, this step is implemented by multiplying the matrix S to the left of the matrix \hat{Q}, and the dimension of the matrix Q is p×N; storing the obtained matrix Q, denoted as Q_{SUM};
It should be noted that: b_{batch} is not greater than a positive integer MAX, the number of batches is j=┌b/MAX┐, and ┌ ┐ represents rounding up. If b is not greater than MAX, then b_{batch}=b, and the number of batches is 1.

Further, the matrix element (G_{batch})ₘₙ in G_{batch} represents the value of the Green function of the Poisson equation corresponding to the distance between the m-th coordinate in the sequence of the position coordinates of the surface sampling points and the n-th coordinate in the sequence of the position coordinates of the internal sampling points.

S34: Performing residual fitting on Q_{SUM}, and finally obtaining the converged equivalent charge matrix Q_{SUM}; including:
Multiplying the matrix Q stored in Step S33 to the right of the left-hand side matrix G_{batch}, obtaining the matrix B_{batch}′=G_{batch}Q; subtracting the matrix B_{batch} from the right-hand side matrix B_{batch}′ to update B_{batch}, obtaining a new right-hand side matrix B_{batch};
Repeatedly executing Step S33, accumulating the obtained new matrix Q into the previously stored matrix Q_{SUM}, until the stored matrix Q_{SUM} converges, thereby obtaining the final converged equivalent charge matrix Q_{SUM};
S35: Accumulating and summing each column in the converged equivalent charge matrix Q_{SUM} according to a rule that the internal sampling points of the same conductor belong to the same summation sequence, obtaining the final parasitic capacitance matrix, and its dimension is N×N.

It should be noted that the form of the Green function of the Poisson equation mentioned in Step S32 in the three-dimensional space is

$$\frac{1}{4 π ε} {( ‖ r - {r}^{′} ‖ )}^{- 1} ,$$

where ε represents the relative dielectric constant, and ∥r−r′∥ represents an Euclidean distance between the surface sampling points and the internal sampling points.

In Step S32, right-multiplying the matrix S causes the column space dimension of the left-hand side matrix G_{batch} to be greatly reduced, thereby causing the scale of the sum (GS)^{T}GS of the finally obtained left-hand side matrix and the sum (GS)^{T}B of the right-hand side matrix to be significantly reduced compared to that without the processing of the matrix S, as shown in FIG. 2.

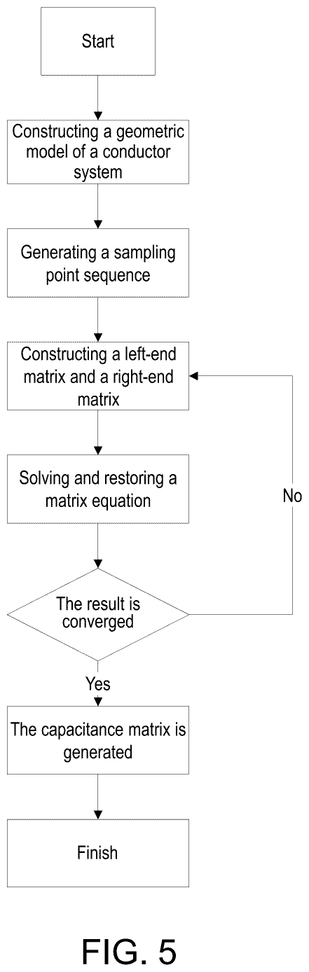

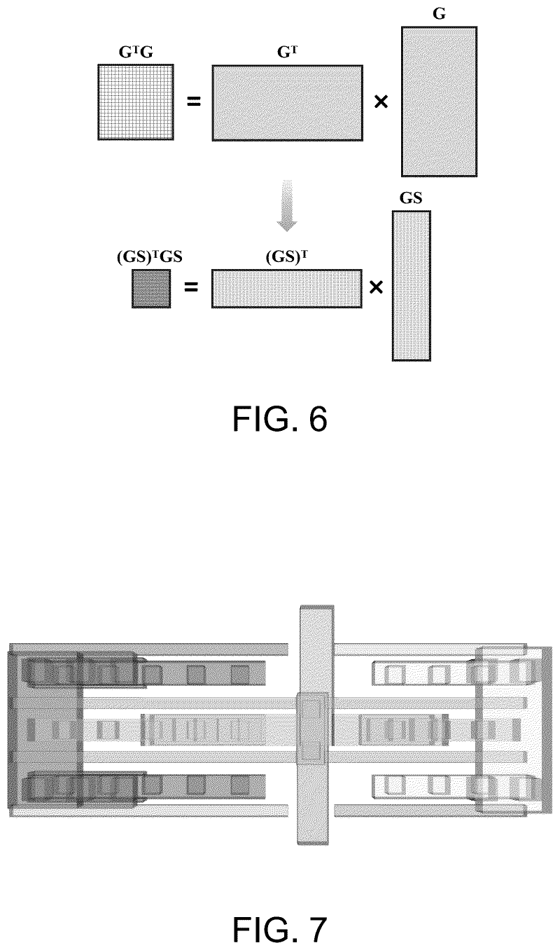

In Step S33, after accumulating the calculated left-hand side matrix (G_{batch}S)^{T}G_{batch}S and the right-hand side matrix (G_{batch}S)^{T}B_{batch} into the previously stored sum of the left-hand side matrix and the sum of the right-hand side matrix respectively, the memory occupied by the matrix (G_{batch}S)^{T}G_{batch}S and the matrix (G_{batch}S)^{T}B_{batch} may be cleared, thereby causing the memory occupation of the overall process to be significantly reduced. FIG. 6 is a comparison diagram of effects before and after using random matrix compression provided by an embodiment of the disclosure. The above process refers to FIG. 5, FIG. 5 is a flowchart of generating the matrix, and the above steps are detailed process diagrams.

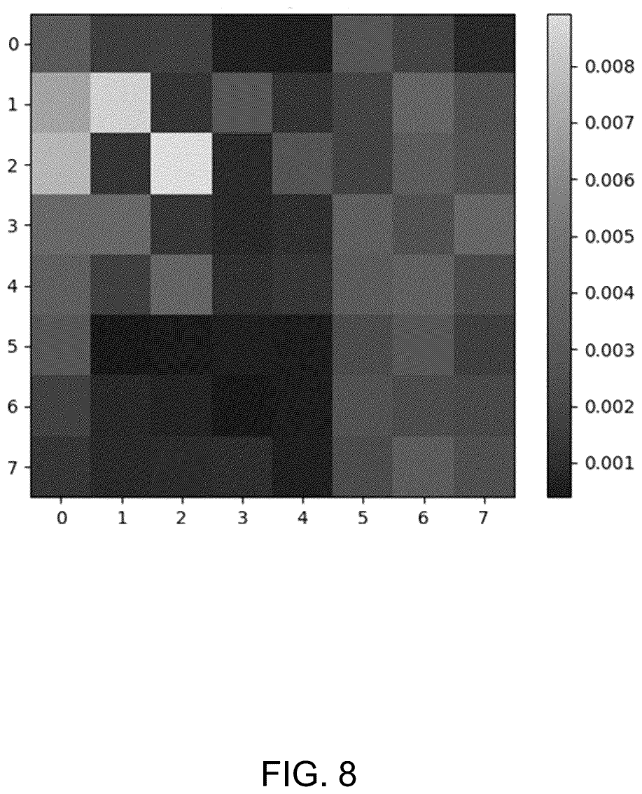

The interconnect line conductor structure diagram shown in FIG. 7 is an inverter, which is an important component unit in very large scale integrated circuits. In the process of solving this structure with the method in this embodiment, a total of 66,609 surface sampling points and 122,535 internal sampling points were selected, the number of conductors N is 8, and the column space dimension A of the random matrix k is equal to 3000. The comparison between the finally obtained capacitance matrix and the capacitance matrix obtained by other commercial software is shown in FIG. 8.

In FIG. 8, each colored block corresponds to a value representing the relative error between the capacitance matrix obtained by this method and the corresponding elements of the capacitance matrix obtained by other commercial software. It may be observed that the relative error is within 1%, demonstrating the reliability of this method in terms of accuracy. Furthermore, in this embodiment, the time consumed by this method is only 7.3 seconds, which is significantly faster than the 69 seconds taken by other commercial software, proving the superiority of this method in terms of speed.

The method for extracting the parasitic capacitance of the interconnect lines of the integrated circuit, as described in this embodiment, represents the first solution that fully utilizes stochastic numerical linear algebra for acceleration. This approach employs random matrix compression to decompose large-scale matrix solutions into a series of smaller-scale matrix problems, thereby surpassing existing commercial software in terms of memory usage and computational speed, while ensuring precision is maintained.

### Embodiment 2

The present disclosure also relates to an electronic device, including a memory and a processor, wherein the memory stores a computer program, and the processor implements the steps of the above method when executing the computer program.

The aforementioned electronic device may include computing devices such as desktop computers, laptops, handheld computers, and cloud servers. The term “processor” may refer to a Central Processing Unit (CPU) or may also encompass other general-purpose processors, Digital Signal Processors (DSP), Application Specific Integrated Circuits (ASIC), Field Programmable Gate Arrays (FPGA), or other programmable logic devices, discrete gate or transistor logic devices, discrete hardware components, and the like. The memory may be utilized for storing computer programs and/or modules, which the processor can execute or run to perform various functions of the electronic device, by retrieving and processing data stored within the memory.

The related technical solutions are the same as above and will not be repeated here.

### Embodiment 3

The present disclosure also relates to a computer-readable storage medium having a computer program stored thereon, wherein the computer program implements the steps of the above method when executed by a processor.

Specifically, the memory may include a high-speed random access memory and may also encompass a non-volatile memory such as hard drives, memory, plug-in hard drives, Smart Media Cards (SMC), Secure Digital (SD) cards, Flash Cards, at least one disk storage device, flash memory devices, or other volatile solid-state memory devices.

The related technical solutions are the same as above and will not be repeated here.

It is readily understood by those skilled in the art that the foregoing description is merely a preferred embodiment of the present disclosure and is not intended to limit the disclosure. Any modifications, equivalent substitutions, and improvements made within the spirit and principles of the present disclosure should be included within the scope to be protected by the present disclosure.

What is claimed is:

1. A method for extracting parasitic capacitance of interconnect lines of an integrated circuit, comprising:
S1: constructing a sequence of position coordinates of surfaces and internal sampling points of each of the conductors for which parasitic capacitance is to be extracted, and serving each of the internal sampling points as a position of an equivalent point charge;
S2: acquiring a set of potential values of all of the surface sampling points, wherein the set of the potential values of the surface sampling points is provided for constructing a sampling point potential matrix;
S3: constructing a neural network structure composed of an input layer, a single hidden layer and an output layer, wherein the position coordinates of the surface sampling points serve as an input of the neural network, a mean square error between ideal surface potential values corresponding to the surface sampling points one by one and an output of the neural network serves as a loss function, the number of neurons is the same as the number of all of the equivalent point charges corresponding to all conductors, a Green function of a Poisson equation in a three-dimensional space serves as an activation function of the single hidden layer, and position coordinates of all of the equivalent point charges serve as center coordinates of the activation function of the hidden layer, based on the set of the position coordinates of the surface sampling points of all of the conductors and the corresponding set of the ideal surface potential values one by one, training weight coefficients of each of the neurons in the single hidden layer of the neural network, correspondingly serving as equivalent charge values of each of the equivalent point charges to obtain the equivalent charge values of all of the equivalent point charges in each of the conductors; and
S4: adopting the equivalent charge values of all of the equivalent point charges in each of the conductors to calculate a charge quantity of the conductor to calculate an interconnect capacitance between every two of the conductors, and calculating and acquiring a parasitic capacitance matrix of the conductors.

2. The extraction method according to claim 1, wherein the method for constructing the set of the coordinates for the surface sampling points is as follows:
reading a physical layout binary file of the integrated circuit and a file recording information of each process layer in the integrated circuit, and establishing a three-dimensional spatial model of each of the conductors in the integrated circuit;
according to the three-dimensional spatial model of each of the conductors, sampling a preset number of sampling points on a surface of the conductor through a uniform random sampling mode or a uniform grid sampling mode, and acquiring the set of the position coordinates of the surface sampling points.

3. The extraction method according to claim 1, wherein the construction method for the set of the position coordinates of the internal sampling point is as follows:
reading a physical layout binary file of the integrated circuit and a file recording information of each process layer in the integrated circuit, and establishing a three-dimensional spatial model of each of the conductors in the integrated circuit;
according to the three-dimensional spatial model of each of the conductors, configuring all of the internal sampling points to be distributed on a surface of a three-dimensional closed solid structure obtained by proportionally reducing each original side length of the conductor according to a preset sampling ratio parameter a, sampling an interior of the conductor, and acquiring the set of the position coordinates of the internal sampling points.

4. The extraction method according to claim 1, wherein when the conductor with an irregular surface exists in the integrated circuit, each of the conductors with the irregular surface is regarded as a conductor with a regular surface to execute steps S1 to S3, according to an actual surface of the conductor with the irregular surface, steps S1 to S3 are executed again, where the number of the surface sampling points and the internal sampling points obtained in both samplings of step S1 are identical, and initial values of the weight coefficients of each of the neurons in the neural network during the second execution of steps S1 to S3 are the weight coefficients obtained after the first execution of steps S1 to S3, and step S4 is executed using the equivalent charge values of all of the equivalent point charges obtained in each of the conductors.

5. The extraction method according to claim 1, wherein the weight coefficients of each of the neurons in the single hidden layer of the neural network are trained using either a gradient descent method or a least squares method.

6. The extraction method according to claim 5, wherein the process of training the weight coefficients of each of the neurons in the single hidden layer of the neural network using the least squares method comprises the following steps:
S31: constructing a sampling point potential matrix B, comprising: sequentially selecting one of the N conductors, setting the potential value of the surface sampling points corresponding to the conductor to 1, and setting the potential values of the surface sampling points corresponding to the remaining conductors to 0, thereby obtaining a set of the potential values of all of the surface sampling points, i.e., a right-hand side vector, combining the N right-hand side vectors into a right-hand side matrix B=[b₁ . . . b_{N}], i.e., a potential matrix B;
S32: constructing a random matrix X and a matrix U, wherein the matrix U is constructed according to the following rules: sequentially selecting one of the N conductors, setting values of the internal sampling points of the conductor to 1, setting values of the internal sampling points of the remaining conductors to 0, and obtaining a set of values of all of the internal sampling points, i.e., a vector, combining the N vectors into a matrix U=[u₁ . . . u_{N}], combining X and U into a new matrix S=[X U];
S33: extracting rows from the right-hand side matrix B in batches sequentially, wherein the number of the rows extracted in each of the batches is b_{patch}, obtaining a new right-hand side matrix B_{batch}, simultaneously constructing a left-hand side matrix G_{batch}, wherein the number of matrix rows constructed in each of the batches is b_{batch}, multiplying the matrix S to the right of the left-hand side matrix G_{batch} to obtain G_{batch}S, left-multiplying a transpose of the matrix G_{batch}S to the left-hand side matrix G_{batch}S and the right-hand side matrix B_{batch} respectively, obtaining the left-hand side matrix (G_{batch}S)^{T}G_{batch}S and the right-hand side matrix (G_{batch}S) B_{batch} respectively, after processing all of the batches, obtaining (GS)^{T}GS and (GS)^{T}B as a final left-hand side matrix and a right-hand side matrix to be solved, solving a matrix equation (GS)^{T}GS\hat{Q}=(GS)^{T}B, multiplying the matrix S to the left of a matrix \hat{Q} to obtain a matrix Q, storing the obtained matrix Q, which is denoted as Q_{SUM};
S34: performing residual fitting on Q_{SUM}, and finally obtaining the converged equivalent charge matrix Q_{SUM};
S35: accumulating and summing each column in the converged equivalent charge matrix Q_{SUM} according to a rule that the internal sampling points of the same conductor belong to a same summation sequence.

7. The extraction method according to claim 6, wherein in step S34, performing the residual fitting on Q_{SUM} comprises:
multiplying the matrix Q stored in step S33 to the right of the left-hand side matrix G_{batch}, obtaining a matrix B_{batch}′=G_{batch}Q, subtracting the matrix B_{batch} from the right-hand side matrix B_{batch}′ to update B_{batch}, obtaining a new right-hand side matrix B_{batch};
repeatedly executing step S33, accumulating the obtained new matrix Q into the previously stored matrix Q_{SUM}, until the stored matrix Q_{SUM} converges, thereby obtaining the final converged equivalent charge matrix Q_{SUM}.

8. The extraction method according to claim 6, wherein in step S33, b_{batch} is not, greater than a positive integer MAX, the number of batches is j=┌b/MAX┐, and ┌ ┐ represents rounding up.

9. The extraction method according to claim 6, wherein if b is not greater than MAX, then b_{batch}=b, and the number of the batches is 1.

10. The extraction method according to claim 6, wherein a matrix element (G_{batch})ₘₙ in the G_{batch} represents a value of the Green function of the Poisson equation corresponding to a distance between an m-th coordinate in the sequence of the position coordinates of the surface sampling points and an n-th coordinate in the sequence of the position coordinates of the internal sampling points.

11. The extraction method according to claim 5, wherein when employing the least squares method to train the weight coefficients of each of the neurons in the single hidden layer of the neural network, after the least squares training is completed, another set of the position coordinates of the internal sampling points is constructed for each of the conductors, based on the equivalent charge values of all of the equivalent point charges corresponding to each of the conductors obtained from the current training, an electrostatic potential excited by all of the equivalent point charges on the conductor at each of the surface sampling points is calculated, a difference between the electrostatic potential corresponding to each of the surface sampling points and the ideal surface potential value of the conductor is determined, the mean square error between the differences, corresponding to the surface sampling points one by one, and the output of the neural network is used as the loss function, the neural network structure is reconstructed and trained anew to obtain the equivalent charge values of all of the equivalent point charges for each of the conductors, as determined by two sets of the position coordinates of the internal sampling points.

12. An electronic device, comprising a memory and a processor, wherein the memory stores a computer program, and the processor implements the steps of the method according to claim 1 when executing the computer program.

13. A computer-readable storage medium having a computer program stored therein, wherein the computer program controls a device where the storage medium is located to implement the steps of the method according to claim 1 when executed by a processor.
